(19) United States
(12) Patent Application Publication
(10) Pub. No.: US 2010/0123119 A1
(43) Pub. Date: May 20, 2010

(54) LIGHT EMITTING DIODE HAVING INDIUM NITRIDE

(75) Inventors: Dae Won Kim, Ansan-si (KR); Dae Sung Kal, Ansan-si (KR); Kyung Hee Ye, Ansan-si (KR); Hong Jae Yoo, Ansan-si (KR)

Correspondence Address: H.C. PARK & ASSOCIATES, PLC, 8500 LEESBURG PIKE, SUITE 7500, VIENNA, VA, 22182, US

(73) Assignee: SEOUL OPTO DEVICE CO., LTD., Ansan-si (KR)

(21) Appl. No.: 12/620,218

(22) Filed: Nov. 17, 2009

(30) Foreign Application Priority Data
Nov. 20, 2008 (KR) 10-2008-0115475
Dec. 29, 2008 (KR) 10-2008-0135165

(51) Int. Cl. H01L 33/00

(52) U.S. Cl. 257/13; 257/14; 257/94; 257/103; 257/E33.008; 257/E33.023

(57) ABSTRACT

The present invention relates to a light emitting diode (LED) including an n-type nitride semiconductor layer, a p-type nitride semiconductor layer, and an active region interposed between the n-type nitride semiconductor layer and the p-type nitride semiconductor layer. The active region may include an InGaN quantum well layer. The LED may further include a super lattice layer interposed between the n-type nitride semiconductor layer and the active region. The super lattice layer may be a structure wherein InN layers and InₓGa₁₋ₓN (0≦x<1) layers are alternately stacked. The active layer may be formed on the InGaN/InₓGa₁₋ₓN super lattice layer, so that strain can be relieved in the active region and so that crystallinity of the quantum well can be improved to increase an electron-hole recombination rate.

### CROSS REFERENCE TO RELATED APPLICATIONS

This application claims priority from and the benefit of Korean Patent Application No. 10-2008-0115475, filed on Nov. 20, 2008, and Korean Patent Application No. 10-2008-0135165, filed on Dec. 29, 2008, which are hereby incorporated by reference for all purposes as if fully set forth herein.

### BACKGROUND OF THE INVENTION

1. Field of the Invention

Exemplary embodiments of the present disclosure relate to a light emitting diode (LED) and, more particularly, to a light emitting diode including indium nitride.

2. Discussion of the Background

Generally, nitride-based semiconductors are widely used in ultraviolet (UV), and blue/green light emitting diodes or laser diodes for light sources of full-color displays, traffic lights, general lighting fixtures, and optical communication devices. A light emitting device having a nitride-based semiconductor may include an active layer of a multi-quantum well structure between a n-type nitride semiconductor layer and a p-type nitride semiconductor layer, and may emit light by recombination of electrons and holes in the active layer.

Since such a conventional nitride-based semiconductor has a lattice mismatch of 11% between gallium nitride (GaN) and indium nitride (InN), an InGaN-based multi-quantum well structure may undergo severe strain at an interface between a quantum well and a quantum barrier. Such strain causes deterioration of internal quantum efficiency by inducing a piezoelectric field in the quantum well. For example, for a green light emitting diode, a high indium amount in the quantum well further deteriorates internal quantum efficiency, which is affected by the piezoelectric field.

The strain generated in the multi-quantum well structure is affected by the n-type nitride semiconductor layer adjacent to the active region. The greater the lattice mismatch between the quantum well layer and the n-type nitride semiconductor layer (e.g., an n-type contact layer), the more severe the strain induced in the active region. Such strain increases lattice defects such as dislocations in the quantum well layer to thereby deteriorate luminescence efficiency, and to further increase the piezoelectric field in the quantum well layer, thereby shifting a luminescence wavelength while increasing a forward voltage of the light emitting diode.

Further, in such conventional nitride-based compound semiconductors, the mobility of electrons is known to be 10 times or more than that of holes. Accordingly, the electrons reach a p-type nitride semiconductor layer faster than the holes through the multi-quantum well structure, and can flow into the p-type nitride semiconductor layer without recombination with the holes. To prevent this phenomenon and confine the electrons in the multi-quantum well structure, an electron blocking layer (EBL) is generally used.

However, a relatively wide energy band-gap of the electron blocking layer obstructs introduction of the holes into the multi-quantum well structure, thereby increasing the forward voltage. Furthermore, the electron blocking layer is formed of aluminum gallium nitride (AlGaN), which is grown at a relatively high temperature. An InGaN layer formed as an upper layer of the active region may become dissociated at the AlGaN growing temperature. Dissociation of the InGaN layer may deteriorate the quality of the active region, thereby promoting non-radiative recombination.

The p-type nitride semiconductor layer is generally composed of a magnesium (Mg)-doped GaN layer. However, an increase in hole-concentration by doping Mg into a GaN layer is restricted to an order of 10¹⁸. As a result, the p-type nitride semiconductor layer has a relatively high specific resistance and thus undergoes restriction in reduction of the forward voltage.

### SUMMARY OF THE INVENTION

Exemplary embodiments of the present invention provide a light emitting diode having a relieved strain in an active region.

Additional features of the invention will be set forth in the description which follows, and in part will be apparent from the description, or may be learned by practice of the invention.

Exemplary embodiments of the present invention disclose a light emitting diode including a first semiconductor layer, a second semiconductor layer, an active region, and a super lattice layer. The active region of a multi-quantum well structure is interposed between the first semiconductor layer and the second semiconductor layer. The active region includes a quantum well layer. The super lattice layer is interposed between the first semiconductor layer and the active region. The super lattice layer comprises a first material layer and a second material layer alternately stacked.

Exemplary embodiments of the present invention disclose a light emitting diode including a first semiconductor layer, a second semiconductor layer, an active region, and a super lattice layer. The active region of a multi-quantum well structure is interposed between the first semiconductor layer and the second semiconductor layer. The active region includes a quantum well layer. The super lattice layer is interposed between the first semiconductor layer and the active region. The super lattice layer comprises a first material layer, a second material layer, and a third material layer alternately stacked.

Exemplary embodiments of the present invention disclose a light emitting diode including a first semiconductor layer, a second semiconductor layer, an active region, and a multilayer structure. The active region of a multi-quantum well structure is interposed between the first semiconductor layer and the second semiconductor layer. The active region includes a quantum well layer. The multilayer structure is interposed between the second semiconductor layer and the active region. The multilayer structure comprises a first material layer and a second material layer stacked alternately at least twice.

Exemplary embodiments of the present invention disclose a light emitting diode including an n-type nitride semiconductor layer, a p-type nitride semiconductor layer, an active region, and an indium nitride (InN) layer. The active region is interposed between the n-type nitride semiconductor layer and the p-type nitride semiconductor layer. The active region includes an indium gallium nitride (InGaN) quantum well layer. The InN layer is disposed on and under the active region.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a cross-sectional view of a light emitting diode according to exemplary embodiments of the present invention.

FIG. 2 is a cross-sectional view of a light emitting diode according to exemplary embodiments of the present invention.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Hereinafter, exemplary embodiments of the present invention are described in detail with reference to the accompanying drawings.

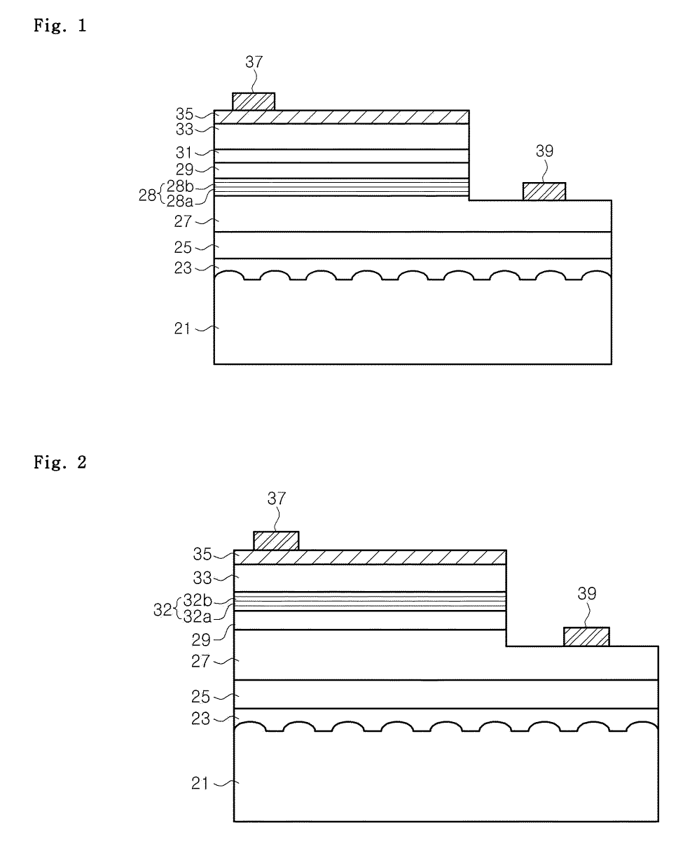

FIG. 1 is a cross-sectional view of a light emitting diode according to exemplary embodiments of the present invention.

Referring to FIG. 1, the light emitting diode (LED) may include a substrate 21, an n-type nitride semiconductor layer 27, a super lattice layer 28, an active region 29 of a multi-quantum well structure, and a p-type nitride semiconductor layer 33. Further, a nucleus layer 23 and an un-doped GaN layer (u-GaN) 25 may be interposed between the substrate 21 and the n-type nitride semiconductor layer 27, and a p-type cladding layer 31 may be interposed between the active region 29 and the p-type nitride semiconductor layer 33. A transparent electrode 35 and a p-electrode 37 may be formed on the p-type nitride semiconductor layer 33, and an n-electrode 39 may be formed on the n-type nitride semiconductor layer 27.

The substrate 21 may include, but is not limited to, sapphire, silicon carbide (SiC), and spinel. For example, the substrate 21 may be a patterned sapphire substrate (PSS) as shown in FIG. 1.

The nucleus layer 23 may be formed of AlN or GaN at a low temperature of 400° C.˜600° C. to form the u-GaN layer 25 on the substrate 21. The nucleus layer 23 may have any suitable thickness, for example, 25 nm.

The u-GaN layer 25 may be formed on the nucleus layer 23, may prevent or reduce generation of defects, such as dislocations, between the substrate 21 and the n-type nitride semiconductor layer 27, and may be grown at relatively higher temperatures. The n-type nitride semiconductor layer 27 may be formed on the u-GaN layer 25 and may be doped with an n-type impurity such as silicon (Si) or Germanium (Ge). The n-electrode 39 can be formed on at least a portion of the n-type semiconductor layer 27.

The super lattice layer 28 may be formed on the n-type nitride semiconductor layer 27, and may have a structure in which InN layers 28a and InₓGa₁₋ₓN (0≦x<1) layers 28b are alternately stacked. Layers 28a and 28b may be doped with an n-type impurity and, in some cases, the InGaN layer 28b may have a higher dopant impurity concentration than the InN layer 28a. In some cases, the InN layer 28a may not be doped with an impurity. A super lattice layer 28 may be formed by repeatedly supplying and blocking a Ga source, and by growing the InN layers 28a and the InₓGa₁₋ₓN layers 28b at different temperatures.

An impurity, for example, Si, doped into the InN/InₓGa₁₋ₓN super lattice layer 28 may prevent a dislocation induced in a lower layer from transferring to an upper layer. As a result, crystallinity of the active region 29 formed on the super lattice layer 28 can be improved. The super lattice layer 28 may have two or more periods of stacks. For example, in some cases, the super lattice layer 28 may have about 20 periods of stacks. Although the crystallinity can be further improved as the number of stacking periods increases, an excessive increase in the number of stacking periods is not desirable due to an increase in processing time.

Each layer in the super lattice layer 28 may have any suitable thickness, for example, a thickness of 10 nm or less. Although the total thickness of the super lattice layer 28 may not be specifically limited, the thickness of the super lattice layer 28 may be set below a total thickness of the active region 29. For example, the total thickness may be, for example, below about 100 nm˜150 nm, since an excessively thick super lattice layer 28 can cause an increase of the forward voltage, Vf. The InₓGa₁₋ₓN layer 28b may be thicker than the InN layer 28a. A thick impurity-doped InₓGa₁₋ₓN layer 28b may have a relatively higher resistance compared to a thin one, and may therefore improve current distribution.

An InGaN layer of the active region 29 may have a wider band gap than the InN layer 28a. The InₓGa₁₋ₓN layer 28b may be connected to the active region 29. Further, the InₓGa₁₋ₓN layer 28b in the supper lattice layer 28 may have a lower In content than the InGaN quantum well layer. Accordingly, carriers can be efficiently confined in the active region 29, thereby improving luminescence efficiency.

The InₓGa₁₋ₓN layers 28b of the super lattice layer 28 may have the same In content, but are not limited thereto. For example, the InₓGa₁₋ₓN layers 28b of the super lattice layer 28 may increase in In content in a direction towards the active region 29.

The active region 29 may have a multi-quantum well structure wherein quantum well layers and quantum barrier layers are alternately stacked. The quantum well layer may include an InGaN layer. The quantum barrier layer may also include an InGaN layer. Accordingly, the multi-quantum well structure may include the InGaN quantum well layer and the InGaN quantum barrier layer, which may be alternately stacked. The multi-quantum well structure may be formed on the InN/InₓGa₁₋ₓN super lattice layer 28, so that strain can be further relieved in the active region 29. The active region 29 may have the InGaN/InGaN quantum well structure, so that conductivity of the quantum well structure can be further improved, thereby lowering the forward voltage Vf of the light emitting diode.

In some cases, the InₓGa₁₋ₓN layer 28b of the super lattice layer 28 may have the same or similar In content as that of the InGaN quantum barrier layer. For example, when the InGaN quantum barrier layer has an In content of 2%, the InGaN layer 28b of the super lattice layer 28 may have an In content of about 2%. Since a difference in lattice constant between the InGaN layers of the InGaN quantum barrier layer and the super lattice layer 28 is not large, the InGaN layer of the InGaN quantum barrier layer may adjoin the InGaN layer 28b of the super lattice layer 28.

The p-type cladding layer 31 may be formed of AlGaN and the p-type nitride semiconductor layer 33 may be formed of GaN.

The transparent electrode 35 may be formed of Nickel (Ni)/Gold (Au) or indium tin oxide (ITO) on the p-type nitride semiconductor layer 33. The p-electrode 37 may be formed on the transparent electrode 35 using any suitable process, for example, a lift-off process. The n-electrode 39 may be formed of Titanium (Ti)/Al on the n-type nitride semiconductor layer 27 using a lift-off process.

Conventionally, when an InGaN-based quantum well layer is formed on a GaN layer, the InGaN layer has a higher lattice constant than that of the GaN layer, thereby inducing compressive strain in the InGaN quantum well layer. As a result, a piezoelectric field is induced in the InGaN quantum well layer, and luminescence efficiency deteriorates. According to exemplary embodiments of the present invention, an LED may have an InN layer 28a (in the super lattice layer 28), which has a higher lattice constant than the InGaN layer 28b. As a result, compressive strain in the InGaN quantum well layer can be further relieved. Furthermore, a super lattice layer 28 may be formed by alternately stacking InN layers 28a, which have a higher lattice constant than the InGaN quantum well layer, and InₓGa₁₋ₓN layers 28b, which have a lower lattice constant than the InGaN quantum well layer, so that the strain induced in the InGaN quantum well layer can be controlled.

Although the InN/InₓGa₁₋ₓN (0<x<1) super lattice layer 28 is described hereinabove, an InN/InₓGa₁₋ₓN (0<x<1)/GaN super lattice layer may also be used in an LED. The InN/InₓGa₁₋ₓN (0<x<1)/GaN super lattice layer can control the strain induced in the InGaN quantum well layer. The InₓGa₁₋ₓN layer or the GaN layer may adjoin the quantum barrier layer. If the quantum barrier layer is the InGaN layer, the InₓGa₁₋ₓN layer may adjoin the quantum barrier layer.

Further, in the super lattice layer, the InₓGa₁₋ₓN (0<x<1) layer and the GaN layer may be doped with an impurity, whereas the InN layer may not be doped with an impurity. In some cases, the InₓGa₁₋ₓN (0<x<1) layer and the GaN layer may be doped with an impurity at higher concentrations than the InN layer.

FIG. 2 is a cross sectional view of LED according to exemplary embodiments of the present invention.

Referring to FIG. 2, the LED may include a substrate 21, an n-type nitride semiconductor layer 27, an active region 29 of a multi-quantum well structure, a p-type multilayer 32, and a p-type nitride semiconductor layer 33. Further, as described in FIG. 1, a nucleus layer 23 and an un-doped GaN layer (u-GaN) 25 may be interposed between the substrate 21 and the n-type nitride semiconductor layer 27. A transparent electrode 35 and a p-electrode 37 may be formed on the p-type nitride semiconductor layer 33, and an n-electrode 39 may be formed on the n-type nitride semiconductor layer 27. As described in FIG. 1, a super lattice layer 28 (not shown in FIG. 2) may be interposed between the n-type nitride semiconductor layer 27 and the active region 29.

The substrate 21, nucleus layer 23, u-GaN layer 25, transparent layer 35, p-electrode 37, and n-electrode 39 of FIG. 2 may be similar to those described with reference to FIG. 1, therefore, a detailed description thereof will be omitted.

Referring to FIG. 2, the active region 29 may have a multi-quantum well structure wherein quantum well layers and barrier layers are alternately stacked. The quantum well layer may include an InGaN layer. The barrier layer may also include an InGaN layer. The InGaN/InGaN quantum well structure can improve conductivity of the quantum well structure, thereby lowering the forward voltage of the LED. The barrier layers in the multi-quantum well structure may include a relatively thick barrier layer, a wider band-gap barrier layer, or a p-type impurity doped barrier layer.

The p-type multilayer 32 may have a structure wherein InN layers 32a and InₓGa₁₋ₓN (0≦x<1) layers 32b are alternately stacked at least twice. Layers 32a and 32b may be doped with a p-type impurity, for example, Mg. A InN layer 32a may have a higher dopant impurity concentration than a InGaN layer 32b. Accordingly, in such a configuration, the hole concentration can be increased in the multilayer 32.

The multilayer 32 may be formed by repeatedly supplying and blocking a Ga source, and may be formed by growing the InN layers 32a and the InₓGa₁₋ₓN layers 32b at different temperatures. Generally, the InN layers 32a or InGaN layers 32b are grown at a lower temperature than the u-GaN layer 25. If the substrate 25 temperature is increased after the InGaN layer 32b is grown, the InGaN layer 32b may be dissociated resulting in decreased thickness and deteriorating crystallinity of the InGaN layer 32b. The InN layer 32a or the InGaN layer 32b may adjoin the active layer after formation of the quantum well structure.

Respective layers 32a, 32b in the p-type multilayer 32 may have a thickness in the range of 5 Å˜200 Å, and the multilayer 32 can be formed as a super lattice structure. Although the total thickness of the multilayer 32 may not be specifically limited, the thickness of the multilayer 32 may be below a total thickness of the active region 29. For example, the total thickness of the multilayer 32 may be below about 100 nm˜150 nm, since an excessively thick multilayer 32 can cause an increase of the forward voltage (Vf). The InₓGa₁₋ₓN layer 32b may be thicker than the InN layer 32a. A thin InN layer 32a may have a narrow band gap and may improve current distribution performance.

The InN layer 32a or the InₓGa₁₋ₓN layer 32b may adjoin the active region 29, for example, the InGaN barrier layer. When using the GaN layer 32b, the InN layer 32a may adjoin the active region. The InGaN barrier layer adjoining the multilayer 32 may have a narrower band gap than other barrier layers.

In some cases, the InₓGa₁₋ₓN layers 32b of the multilayer 32 may have the same In content. In other cases, the InₓGa₁₋ₓN layers 32b may have different In contents. In some cases, InₓGa₁₋ₓN layers 32b situated closer to the active region 29 may have an increased In content.

The p-type nitride semiconductor layer 33 may be formed of GaN. The p-type nitride semiconductor layer 33 may be a single layer, or in some cases, multiple layers. The transparent electrode 35 may be formed on the p-type nitride semiconductor layer 33. The p-electrode 37 may be formed on the transparent electrode 35, and the n-electrode 39 may be formed on the n-type nitride semiconductor layer 27.

As apparent from the description hereinabove, according to exemplary embodiments of the present invention, the InN/InₓGa₁₋ₓN super lattice layer or the InN/InₓGa₁₋ₓN/GaN super lattice layer may be formed between the nitride semiconductor layer 27 and the active region 29, so that strain can be relieved in the active region 29, including the InGaN layer, and so that crystallinity of the quantum well structure can be improved to increase the recombination rate of carriers. The InN layer 32a of the LED may have a higher lattice constant than the InGaN quantum well layer, so that compressive strain can be further relieved in the InGaN quantum well layer. As a result, the LED may have improved luminescence efficiency.

In addition, use of the p-type InN/InGaN(GaN) multilayer 32 can improve crystallinity of the p-type nitride semiconductor layer 33 while increasing the hole concentration in the multilayer 32. Furthermore, an electron blocking layer is not used in the LED, and holes do not need to overcome an energy barrier. Accordingly, it is possible to lower the forward voltage of the LED while allowing the holes to be smoothly introduced into the active region. Moreover, the InN layer 32a may be used as the p-type nitride semiconductor, thereby increasing the hole concentration.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A light emitting diode, comprising:
a first semiconductor layer;
a second semiconductor layer;
an active region of a multi-quantum well structure interposed between the first semiconductor layer and the second semiconductor layer, the active region comprising a quantum well layer; and
a super lattice layer interposed between the first semiconductor layer and the active region, the super lattice layer comprising a first material layer and a second material layer alternately stacked.

2. The light emitting diode of claim 1, wherein the first semiconductor layer comprises a n-type nitride semiconductor layer, the second semiconductor layer comprises a p-type nitride semiconductor layer, the first material layer comprises an indium nitride (InN) layer, the second material layer comprises an indium gallium nitride (InₓGa₁₋ₓN) layer, the quantum well layer comprises an indium gallium nitride (InGaN) quantum well layer, wherein the InₓGa₁₋ₓN layer has a lower indium content than the InGaN quantum well layer, and wherein 0≦x<1.

3. The light emitting diode of claim 1, wherein the second material layer is adjacent to the active region.

4. The light emitting diode of claim 1, wherein the active region has a structure comprising an InGaN quantum well layer and an InGaN quantum barrier layer alternately stacked.

5. The light emitting diode of claim 4, wherein the second material layer is directly connected to the InGaN quantum barrier layer.

6. The light emitting diode of claim 5, wherein the second material layer and the InGaN quantum barrier layer comprise the same quantity of indium content.

7. The light emitting diode of claim 1, wherein the super lattice layer comprises a plurality of the first material layers arranged alternatively with a plurality of the second material layers, the second material layers of the super lattice layer increase in In content in a direction towards the active region.

8. The light emitting diode of claim 1, wherein the second material layer comprises a higher dopant impurity concentration than a dopant impurity concentration of the first material layer.

9. The light emitting diode of claim 1, wherein the second material layer is doped with an impurity and the first material layer is not doped with an impurity.

10. The light emitting diode of claim 9, wherein the second material layer is thicker than the first material layer.

11. A light emitting diode, comprising:
a first semiconductor layer;
a second semiconductor layer;
an active region of a multi-quantum well structure interposed between the first semiconductor layer and the second semiconductor layer, the active region comprising a quantum well layer; and
a super lattice layer interposed between the first semiconductor layer and the active region, the super lattice layer comprising a first material layer, a second material layer, and a third material layer alternately stacked.

12. The light emitting diode of claim 11, wherein the first semiconductor layer comprises a n-type nitride semiconductor layer, the second semiconductor layer comprises a p-type nitride semiconductor layer, the first material layer comprises an indium nitride (InN) layer, the second material layer comprises an indium gallium nitride (InₓGa₁₋ₓN) layer, the third material layer comprises a gallium nitride (GaN) layer, the quantum well layer comprises an indium gallium nitride (InGaN) quantum well layer, wherein the second material layer is adjacent to the active region, and wherein 0<x<1.

13. The light emitting diode of claim 11, wherein the second material layer and the third material layer are doped with an impurity, and the first material layer is not doped with an impurity.

14. The light emitting diode of claim 11, wherein the second material layer and the third material layer have a higher dopant impurity concentration than a dopant impurity concentration of the first material layer.

15. A light emitting diode, comprising:
a first semiconductor layer;
a second semiconductor layer;
an active region of a multi-quantum well structure interposed between the first semiconductor layer and the second semiconductor layer, the active region comprising a quantum well layer; and
a multilayer structure interposed between the second semiconductor layer and the active region, the multilayer structure comprising a first material layer and a second material layer stacked alternately at least twice.

16. The light emitting diode of claim 15, wherein the first semiconductor layer comprises a n-type nitride semiconductor layer, the second semiconductor layer comprises a p-type nitride semiconductor layer, the first material layer comprises an indium nitride (InN) layer, the second material layer comprises an indium gallium nitride (InₓGa₁₋ₓN) layer, the quantum well layer comprises an indium gallium nitride (InGaN) quantum well layer, wherein the multilayer structure further comprises a p-type InN layer doped with a p-type impurity, and wherein 0≦x<1.

17. The light emitting diode of claim 16, wherein the p-type InN layer has a higher p-type impurity concentration than the second material layer.

18. The light emitting diode of claim 15, wherein the multilayer structure is adjacent to the active region.

19. The light emitting diode of claim 18, wherein the active region comprises an InGaN quantum well layer and an InGaN barrier layer that are alternately stacked.

20. The light emitting diode of claim 19, wherein the multilayer structure is directly connected to the InGaN barrier layer.

21. The light emitting diode of claim 20, wherein the InGaN barrier layer has a narrower energy band gap than other barrier layers in the active region.

22. The light emitting diode of claim 15, wherein the first material layer and the second material layer each have a thickness of 5 angstroms to 200 angstroms.

23. The light emitting diode of claim 15, wherein the multilayer structure comprises a super lattice structure.

24. The light emitting diode of claim 15, wherein the multilayer structure comprises a plurality of second material layers, and wherein the second material layers increase in In content in a direction towards the active region.

25. A light emitting diode, comprising:
an n-type nitride semiconductor layer;
a p-type nitride semiconductor layer;
an active region interposed between the n-type nitride semiconductor layer and the p-type nitride semiconductor layer, the active region comprising an indium gallium nitride (InGaN) quantum well layer; and
an indium nitride (InN) layer disposed on and under the active region.
